(19) United States
(12) Patent Application Publication
(10) Pub. No.: US 2001/0018796 A1
(43) Pub. Date: Sep. 6, 2001

(54) METHOD OF FORMING MULTILAYER CIRCUIT STRUCTURE

(76) Inventors: MICHAEL G. LEE, SAN JOSE, CA (US); SOLOMON BEILIN, SAN CARLOS, CA (US); WEN-CHOU WANG, CUPERTINO, CA (US)

Correspondence Address: COUDERT BROTHERS, 4 EMBARCADERO CTR #3300, SAN FRANCISCO, CA, 94111

(21) Appl. No.: 09/374,852

(22) Filed: Aug. 16, 1999

(51) Int. Cl. H05K 3/36; H05K 3/20

(52) U.S. Cl. 29/830; 29/831

(57) ABSTRACT

A method for making a multilayer circuit structure using circuit substrates with apertures at edge regions is disclosed. The method includes using a roller element with teeth. The teeth are used to align the circuit substrates during a lamination process.

### FIELD OF THE INVENTION

The present invention relates to methods for making multilayer circuit structures.

### BACKGROUND OF THE INVENTION

Multilayer circuit structures are used in a wide variety of electrical assemblies such as multichip modules. In general, multilayer circuit structures can provide electrical communication between a plurality of chips or other electrical devices. In the formation of a multilayer circuit structure, two or more circuit substrates are joined together so that they electrically communicate with each other. For example, in a typical joining process, a pair of rigid circuit substrates are parallel and are aligned so that the major surfaces thereof confront each other. The substrates are then brought into contact with each other to form a multilayer circuit structure.

While methods such as this one can be used to form a multilayer circuit structure, such methods are not without problems. For example, because the surfaces of the circuit substrates being joined together have a large area and are joined together at approximately the same time, misalignment between the substrates can sometimes occur. If the circuit substrates are misaligned, circuitry on each respective substrate may not be able to communicate with each other as intended, thus increasing the likelihood that the formed circuit structure will be defective. Accordingly, aligning circuit substrates is highly desirable when forming a multilayer circuit structure.

Alignment is even more of a problem when flexible circuit substrates are used to form a flexible multilayer circuit structure. For example, flexible circuit substrates tend to flex and move more readily than rigid circuit substrates, and are much more difficult to align than rigid circuit substrates. Many times, flexible circuit substrates can wrinkle during joining, thus increasing the likelihood that bubbles or blisters will be present in the formed circuit structure.

Embodiments of the invention address these, and other problems in making multilayer circuit structures.

### SUMMARY OF THE INVENTION

Embodiments of the invention are directed to methods for joining circuit substrates, wherein at least one of the circuit substrates is flexible. Advantageously, embodiments of the invention can form reliable circuit structures easily and efficiently.

One embodiment of the invention is directed to a method for forming a flexible multilayer circuit structure. The method comprises: aligning an aperture in a first circuit -substrate and an aperture in a second circuit substrate, wherein the first circuit substrate is flexible; inserting a tooth from a roller element into the aligned apertures of the first and the second circuit substrates; rotating the roller element; and laminating the first circuit substrate to the second circuit substrate.

This and other embodiments of the invention are described with reference to the foregoing Figures.

### BRIEF DESCRIPTION OF THE DRAWINGS

FIG. 1 shows a plan view of a first circuit substrate having apertures.

FIG. 2 is a side view showing how a flexible first circuit substrate can be laminated to a second circuit substrate using a roller element.

FIG. 3 is a side view showing how a flexible first circuit substrate can be laminated to a second circuit substrate using a roller element and a film of material disposed between the first and second circuit substrates.

FIG. 4 is a side view showing how a flexible first circuit substrate can be laminated to a second circuit substrate using a roller element and a liquid dielectric material disposed between the first and second circuit substrates.

### DETAILED DESCRIPTION

Embodiments of the present invention are directed to methods for forming multilayer circuit structures. The multilayer circuit structures can be used to form an electrical assembly such as a multi-chip module.

In a typical embodiment, a first circuit substrate is laminated to a second circuit substrate to form a multilayer circuit structure. The first circuit substrate is flexible, while the second circuit substrate is flexible or rigid. Preferably, one or more rows of apertures are present along opposing edge regions on each of the first and the second circuit substrates. The apertures on the first circuit substrate align with apertures on the second circuit substrate. Teeth from a roller element can be inserted into the aligned apertures, thus maintaining the alignment of the substrates, e.g., during lamination. As the roller element rotates, the teeth of the roller element engage the aligned apertures and preferably move the first and second circuit substrates simultaneously. As they are moved, the first and second circuit substrates pass through a nip present between the roller element and a body. After passing through the nip, the first and second circuit substrates are laminated together. The teeth of the roller element help keep the circuit substrates aligned during lamination. Pressure and/or heat may be applied to the forming circuit structure to help bond the first and second circuit substrates together.

Embodiments of the invention can be more clearly described with respect to FIGS. 1, 2, 3, and 4.

FIG. 1 shows a first circuit substrate 10 having rows of apertures 20 at opposing edge regions. Conductive circuitry (not shown) is typically present between the opposing rows of apertures. The individual apertures 20 extend through the first circuit substrate 10, so that the teeth of a roller element can pass through the apertures and to the apertures of a second circuit substrate. In this regard, the teeth of the roller element are longer than the thickness of the first circuit substrate at the edge regions and are longer than the length of the apertures in the first circuit substrate. The apertures can be formed by any suitable process including photolithography, laser drilling, or punching.

The apertures 20 in the first circuit substrate 10 can have any suitable size, geometry, or arrangement. For example, FIG. 1 shows two respective lines of circular apertures at opposing edge regions of the first circuit substrate 20. In other embodiments, the apertures at opposing edge region portions can be staggered and need not be symmetrical as shown in FIG. 1. Typical apertures sizes can have a width or diameter of at least about 2 mm. In other embodiments, the apertures sizes can have a width or diameter of between about 0.5 mm and about 5 mm.

The first circuit substrate 10 is flexible, and can have any suitable combination of conducting and/or insulating layers. Exemplary insulating layers include polymeric layers (e.g., polyimide) such as thermosetting or thermoplastic layers. Discontinuous conducting layers can be present on an insulating layer and can include a conductor such as copper.

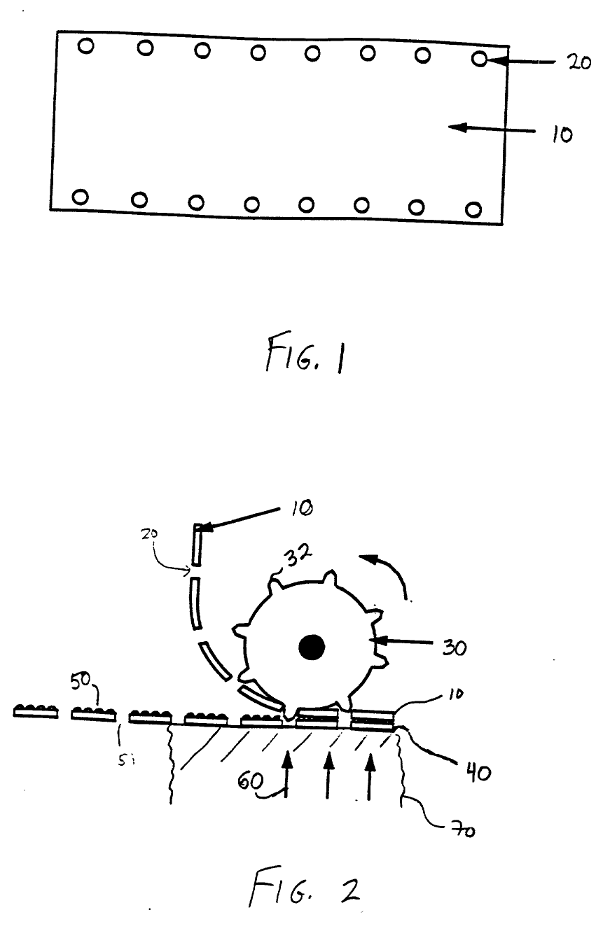

FIG. 2 shows how the flexible first circuit substrate 10 of FIG. 1 is laminated to the second circuit substrate 40. The second circuit substrate 40 can have a similar of different construction or materials as the first circuit substrate. In addition, the second circuit substrate 40 may be rigid or flexible. Preferably, the first and second circuit substrates 10, 40 have similar planar dimensions.

Opposing edge regions of the second circuit substrate 40 preferably have apertures 51. The apertures 51 in the second circuit substrate 40 may pass entirely through the second circuit substrate (e.g., through apertures) as shown in FIG. 2. In other embodiments, the apertures may pass partially (e.g., blind apertures) through the second circuit substrate 10. Regardless of the type of apertures present in the second circuit substrate 40, the apertures 51 are preferably adapted to align with the apertures 20 at the edge regions of the first circuit substrate 10 so that teeth from the roller element 30 can be received in both apertures. Preferably, enough apertures in the first and second circuit substrates are aligned to facilitate the simultaneous movement of both substrates by a roller element 30. In preferred embodiments, the apertures 20 at the edge regions of the first circuit substrate 10 are a mirror image of the apertures 51 at the edge regions of the second circuit substrate 40.

The second circuit substrate 40 can be placed on a moving or non-moving body 70. The body can have a flat surface or a curved surface. For example, the body 70 can have a flat surface such as that provided by a table or a horizontal conveyor apparatus. The body can alternatively have a curved surface. Bodies with curved surfaces can include a roller element such as the roller element 30 adjacent to the first circuit substrate, or a roller element without teeth.

The teeth 32 of the roller element 30 are used to align the apertures in the first and second circuit substrates 10, 40. Aligning the apertures in the first and second circuit substrates also aligns the first and second circuit substrates 10, 40 as well as any circuit patterns thereon (e.g., confronting circuit patterns). As the roller element 30 rotates, the teeth 32 engage the apertures in the flexible circuit substrate, and subsequently or simultaneously, engage apertures in the second circuit substrate. Once the teeth pass through the aligned apertures of the first and second substrates, the rotation of the roller element 30 preferably moves the first and second circuit substrates as they pass through a nip formed by the roller element 30 and the body 40. As the first and second circuit substrates 10, 40 emerge from the nip, they are laminated together to form a multilayer circuit structure.

Heat and optionally pressure may be applied by the roller element 30, the body 40 or by a device external to these components. Heat and pressure are preferably applied to the first and second circuit substrates during or after lamination. Preferred lamination temperatures can be between about 150° C. to about 400° C., while preferred laminating pressures can be between about 20 psi to about 200 psi. The applied heat may also optionally cure any curable material in the formed circuit structure. In FIGS. 2 to 4, for example, heat 60 can be provided by a heating element present in the body 70. In another example, the roller element 30 has a heating element so that the roller element 30 applies heat to the forming circuit structure as it passes through the nip.

The roller element 30 can have any suitable form. For example, the roller element 30 can be a rotatable spool, drum, or roller with teeth at the end regions of the element. The central region of the roller element is preferably smooth and continuous. In other embodiments, the roller element may include a pair of sprockets spaced apart and rotating about a common axle. The sprockets rotate in the vicinity of the edge regions of the first circuit substrate. The teeth 32 on the roller element 30 may be spaced apart and may extend in a radial direction, and can have any suitable shape including cylinders or pyramids.

Any suitable material 50 including a conductive material such as a conductive paste (e.g., solder), conductive adhesive, an anisotropic conductive film, or a conductive post can be present between the first and second circuit substrates 10, 40, prior to or after laminating. Alternatively or additionally, the material 50 can include a dielectric material (e.g., an adhesive dielectric material). For example, the material can be a dielectric layer having plural discrete conductive deposits (e.g., solder deposits) for providing communication between the first and second circuit substrates in the formed structure.

As shown in FIG. 2, for example, the material 50 is disposed on (e.g., by depositing) the inner surface of second circuit substrate 40 prior to laminating. As the roller element 30 rotates, the first and second circuit substrates 10, 40 are laminated together sandwiching the material 50 between them. If, for example, the material 50 includes solder paste, then the pressure and/or heat from the roller element and the surface 40 causes the solder paste to melt and bond (e.g., intermetallic bonds) to conductive pads on the first and second circuit substrates 10, 40, thus providing electrical coupling between the first and second circuit substrates in the formed multilayer circuit structure. In this embodiment, the solder paste preferably includes solder particles and a carrier including a resin and a fluxing agent. The fluxing agent is preferably of the type that is incorporated into the resin so that the generation of loose flux residue after fluxing is minimized. Suitable fluxing agents may include organic acids or derivatives thereof (e.g., cinnamic acid).

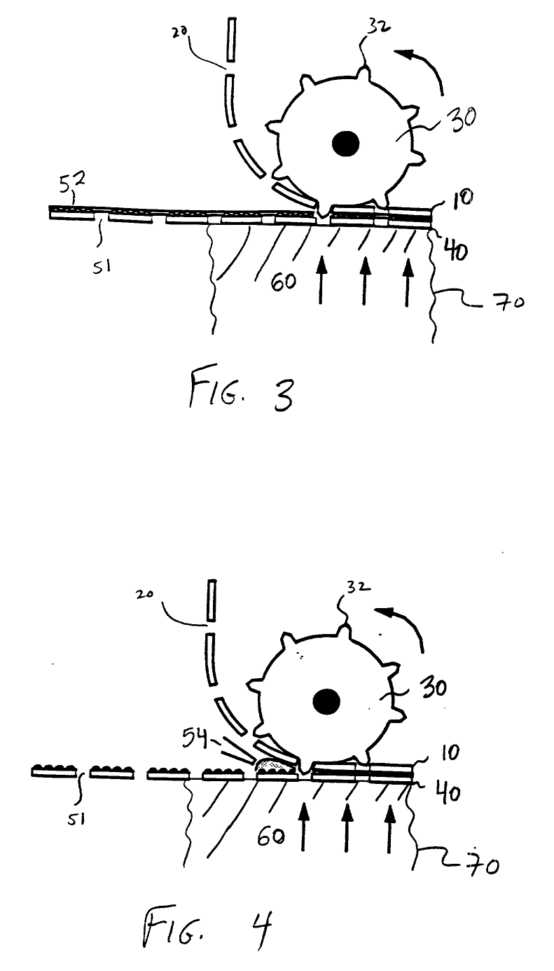

In some embodiments, the material between the first and second circuit substrates is a dielectric material, which can be in the form of a freestanding film or a liquid. Preferably, heat and pressure are applied to the first circuit substrate 10 and to the second circuit substrate 40 with the dielectric material between them so that the dielectric material bonds them together. For example, as shown in FIG. 3, a dielectric film 52 is present on the inner surface of the second circuit substrate 40. Preferably, the dielectric film 52 has edges which are, e.g., disposed inwardly of the edges of the first and second circuit substrates 10, 40. By doing so, the dielectric film 52 does not interfere with the teeth of the roller element 30 passing through the apertures 20 of the first circuit substrate 10 and into the apertures 51 of the second circuit substrate 40. As the teeth of the roller element 30 engage the aligned apertures in the first and second circuit substrates 10, 40, the roller element rotates and preferably moves the first and second circuit substrates 10, 40. As the combination emerges from the nip, the first and second circuit substrates 10, 40 are laminated together with the intermediate dielectric film 52 between the two substrates. Although the dielectric film 52 is shown in FIG. 3 as being disposed adjacent to the second circuit substrate 40 prior to laminating, the film 52 may also be fed from a roll (not shown) to the nip region between the first and second circuit substrates 10, 40. In this embodiment, the first circuit substrate 10, the second circuit substrate 40, and the film 52 may all come in contact substantially simultaneously in the vicinity of the nip.

FIG. 4 shows yet another embodiment of the invention. In this embodiment, a dispenser 54 dispenses a material such as a liquid dielectric material in the vicinity of the nip region and prior to lamination. As the teeth of the roller element 30 engage the aligned apertures of the first and second circuit substrates, they move the first and second circuit substrates as the dielectric material is sandwiched between them. The decreasing space at the nip region molds the liquid material into a film so that a layer of the material resides between the first and second circuit substrates in the formed circuit structure.

Embodiments of the invention reduce the likelihood that blisters will be formed between the substrates. For example, as the first circuit substrate is laminated to the second circuit substrate, air between the first and second circuit substrates is squeezed away from the forming structure as the first and second circuit substrates converge at the nip. Consequently, the likelihood that blisters will be present within the formed multilayer circuit structure are reduced. In addition, because only a small section of the substrates are joined at any one time, this provides improved access to the joints so that flux or other residues may be cleaned more readily (since each joined region will be formed sequentially rather than having all the regions formed at once). Furthermore, the progressive bonding between the two substrates also permits a dielectric material to be applied between the substrates in a gradual manner. This facilitates the formation of a uniform dielectric layer.

Furthermore, multilayer circuit structures can be formed efficiently in embodiments of the invention. For example, the first and the second circuit substrates can be in the form of rolls prior to laminating. Any film of material to be included between the substrates may also be in the form of a roll prior to lamination. The first circuit substrate, the second circuit substrate, and the material can be continuously and simultaneously fed to a nip region between a roller element and a body. As these layers pass through the nip, the layers are laminated together. The laminate may be cut to form plural multilayer circuit structures suitable for use in multichip modules. Accordingly, embodiments of the invention can form multilayer circuit structures with favorable alignment between circuit substrates, efficiently and economically.

Although embodiments of the invention have been described specifically with reference to the joining of first and second circuit substrates, embodiments of the invention can join any suitable number of circuit substrates together to form a multilayer circuit structures. For example, a third circuit substrate (e.g., a flexible or rigid circuit substrate) and may be laminated to the upper or lower side of any previously described structure.

The terms and expressions which have been employed herein are used as terms of description and not of limitation, and there is no intention in the use of such terms and expressions of excluding equivalents of the features shown and described, or portions thereof, it being recognized that various modifications are possible within the scope of the invention claimed. Moreover, any one or more features of any embodiment of the invention may be combined with any one or more other features of any other embodiment of the invention, without departing from the scope of the invention.

What is claimed is:

1. A method for forming a multilayer circuit structure, the method comprising:
aligning an aperture in a first circuit substrate and an aperture in a second circuit substrate, wherein the first circuit substrate is flexible;
inserting a tooth from a roller element into the aligned apertures of the first and the second circuit substrates;
rotating the roller element; and
laminating the first circuit substrate to the second circuit substrate.

2. The method of claim 1 wherein laminating the first circuit substrate to the second circuit substrate comprises laminating the first and second circuit substrates together with a material disposed between the first and second circuit substrates.

3. The method of claim 2 wherein the material comprises a dielectric material.

4. The method of claim 2 wherein the material comprises a conductive material.

5. The method of claim 2 wherein the material comprises solder.

6. The method of claim 1 wherein laminating the first circuit substrate to the second circuit substrate comprises passing the first and second circuit substrate through a nip formed by the roller element and a body.

7. The method of claim 6 wherein the body is has a flat surface.

8. The method of claim 6 wherein the body has a curved surface.

9. The method of claim 1 further comprising heating the first and second circuit substrates.

10. The method of claim 1 wherein laminating the first circuit substrate to the second circuit substrate comprises applying pressure to the first and second circuit substrates.

11. The method of claim 1 further comprising:
depositing a material on the second circuit substrate before laminating.

12. The method of claim 11 wherein the material is a liquid dielectric material.

13. The method of claim 11 wherein the material is a curable liquid dielectric material.

14. The method of claim 11 wherein the material is an adhesive film.

15. The method of claim 11 wherein the material is curable.

16. The method of claim 11 wherein the material comprises a dielectric layer having discrete conductive deposits therein to provide communication between the first and second circuit substrates.

17. The method of claim 1 wherein the first circuit substrate has plural apertures at opposite edge regions of the first circuit substrate.

18. The method of claim 1 wherein the first circuit substrate has plural apertures at opposing edge regions and the second circuit substrate has plural apertures at opposing edge regions, and wherein the apertures on the first circuit substrate and the apertures on the second circuit substrate are mirror images.

19. The method of claim 1 wherein the first circuit substrate comprises a flexible thermoplastic material.

20. The method of claim 1 wherein the second circuit substrate is rigid.
